(19) United States
(12) Patent Application Publication
(10) Pub. No.: US 2026/0231781 A1
(43) Pub. Date: Aug. 6, 2026

(54) SEMICONDUCTOR DEVICE AND METHOD FOR MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Akira EZAKI, Nonoichi Ishikawa (JP); Hiroki OKUYAMA, Nonoichi Ishikawa (JP)

(21) Appl. No.: 19/355,873

(22) Filed: Oct. 10, 2025

(30) Foreign Application Priority Data
Jan. 31, 2025 (JP) 2025-014499

(51) Int. Cl. H10W 70/40; H10P 54/00; H10P 72/70; H10W 74/10; H10W 72/00; H10W 72/30; H10W 90/00

(52) U.S. Cl. CPC H10W 70/417; H10P 54/00; H10P 72/7402; H10W 70/481; H10W 74/129; H10P 72/7416; H10W 72/07353; H10W 72/331; H10W 72/884; H10W 90/736; H10W 90/756

(57) ABSTRACT

The semiconductor devices of the embodiments have a conductive member and a semiconductor chip. The semiconductor chip has a semiconductor substrate on which a semiconductor element is formed, a first electrode formed on a surface on a first side of the semiconductor substrate, and a second electrode formed on a surface on a second side of the semiconductor substrate. The semiconductor substrate has a first portion including an outer peripheral edge of the semiconductor substrate and a second portion disposed away from the outer peripheral edge. A portion of the second electrode formed on the surface on the second side of the first portion is electrically joined to the conductive member. A dimension of the second portion in the thickness direction is greater than a dimension of the first portion in the thickness direction. The second portion protrudes further toward the second side than the first portion.

### CROSS-REFERENCE TO RELATED APPLICATION

This application is based upon and claims the benefit of priority from Japanese Patent Application No. 2025-014499, filed on January 31, 2025; the entire contents of which are incorporated herein by reference.

### FIELD

Embodiments described herein relate generally to a semiconductor device and a method for manufacturing a semiconductor device.

### BACKGROUND

Semiconductor devices including semiconductor chips are known. In such semiconductor devices, for example, when the semiconductor chip is a transistor, it is desirable to thin a semiconductor substrate included in the semiconductor chip to reduce the on-resistance of the semiconductor chip. However, when the semiconductor substrate is thinned, there is a concern that a portion of the semiconductor substrate pushed up by a pin may crack when the semiconductor chip is picked up by being adsorbed and pushed up with the pin during manufacturing of the semiconductor device.

### BRIEF DESCRIPTION OF THE DRAWINGS

FIG. 1 is a cross-sectional view showing a semiconductor device according to a first embodiment, including a cross section taken along I-I of FIG. 2.

FIG. 2 is a view of a part of the semiconductor device according to the first embodiment as viewed from above.

FIG. 3 is a cross-sectional view showing a part of the semiconductor device according to the first embodiment, the cross section being taken along III-III of FIG. 2.

FIG. 4 is an exploded perspective view showing a part of the semiconductor device according to the first embodiment.

FIG. 5 is a flowchart showing a part of a procedure of a method for manufacturing the semiconductor device according to the first embodiment.

FIG. 6 is a perspective view showing a part of the procedure of the method for manufacturing the semiconductor device according to the first embodiment.

FIG. 7A is a perspective view showing a part of a procedure of a second thinning step according to the first embodiment.

FIG. 7B is a perspective view showing another part of the procedure of the second thinning step according to the first embodiment.

FIG. 7C is a perspective view showing still another part of the procedure of the second thinning step according to the first embodiment.

FIG. 8 is a cross-sectional view showing a part of a procedure of a pickup step according to the first embodiment.

FIG. 9 is a cross-sectional view showing a part of a procedure of a step of fixing a semiconductor chip to a first conductive member according to the first embodiment.

FIG. 10 is a cross-sectional view showing a part of a semiconductor device according to a modification example of the first embodiment.

FIG. 11 is an exploded perspective view showing a part of a semiconductor device according to a second embodiment.

FIG. 12 is a view of a part of the semiconductor device according to the second embodiment as viewed from above.

### DETAILED DESCRIPTION

The semiconductor devices of the embodiments have a conductive member, and a semiconductor chip fixed to the conductive member. The semiconductor chip has a semiconductor substrate on which a semiconductor element is formed, a first electrode formed on a surface on a first side of the semiconductor substrate in the thickness direction, and a second electrode formed on a surface on a second side opposite to the first side of the semiconductor substrate in the thickness direction. The semiconductor substrate has a first portion including an outer peripheral edge of the semiconductor substrate as viewed in the thickness direction and a second portion disposed away from the outer peripheral edge as viewed in the thickness direction. The second portion is disposed at a position different from the first portion as viewed in the thickness direction. A surface on the first side of the first portion is a part of the surface on the first side of the semiconductor substrate. A surface on the first side of the second portion is another part of the surface on the first side of the semiconductor substrate. A surface on the second side of the first portion is a part of the surface on the second side of the semiconductor substrate. A surface on the second side of the second portion is another part of the surface on the second side of the semiconductor substrate. The conductive member is disposed on the second side of the semiconductor chip. A portion of the second electrode formed on the surface of the first portion on the second side is electrically joined to the conductive member via a bonding material. A dimension of the second portion in the thickness direction is greater than a dimension of the first portion in the thickness direction. The second portion protrudes further toward the second side than the first portion.

Hereinafter, semiconductor devices and methods for manufacturing the semiconductor devices according to embodiments will be described with reference to the drawings.

In the drawings, the thickness direction of the semiconductor substrate in each embodiment is indicated as a Z-axis direction, a direction orthogonal to the thickness direction of the semiconductor substrate is indicated as an X-axis direction, and a direction orthogonal to both the Z-axis direction and the X-axis direction is indicated as a Y-axis direction. In the following description, the X-axis direction is referred to as a “first direction X,” the Y-axis direction is referred to as a “second direction Y,” and the Z-axis direction is referred to as a “thickness direction Z.” The first direction X is a direction orthogonal to the thickness direction Z. The second direction Y is a direction orthogonal to both the thickness direction Z and the first direction X. In addition, a side in the thickness direction Z toward which the arrow of the Z-axis is directed (+Z side) is referred to as an “upper side,” and a side opposite to the side in the thickness direction Z toward which the arrow of the Z-axis is directed (-Z side) is referred to as a “lower side.” In the following embodiments, the upper side corresponds to a “first side” in the thickness direction Z. The lower side corresponds to a “second side” in the thickness direction Z. The terms “upper side” and “lower side” are merely names used to describe relative positional relationships among respective components, and actual arrangement relationships and the like may be arrangement relationships and the like other than those indicated by such names.

### First embodiment

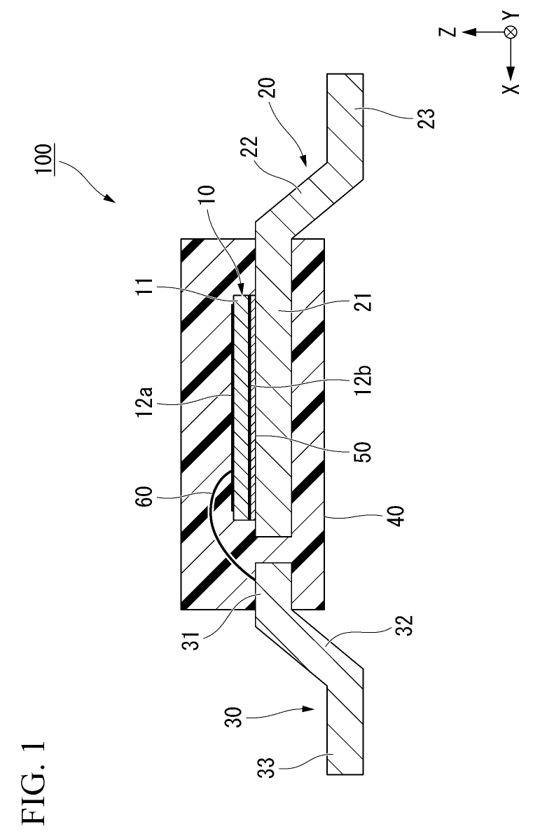

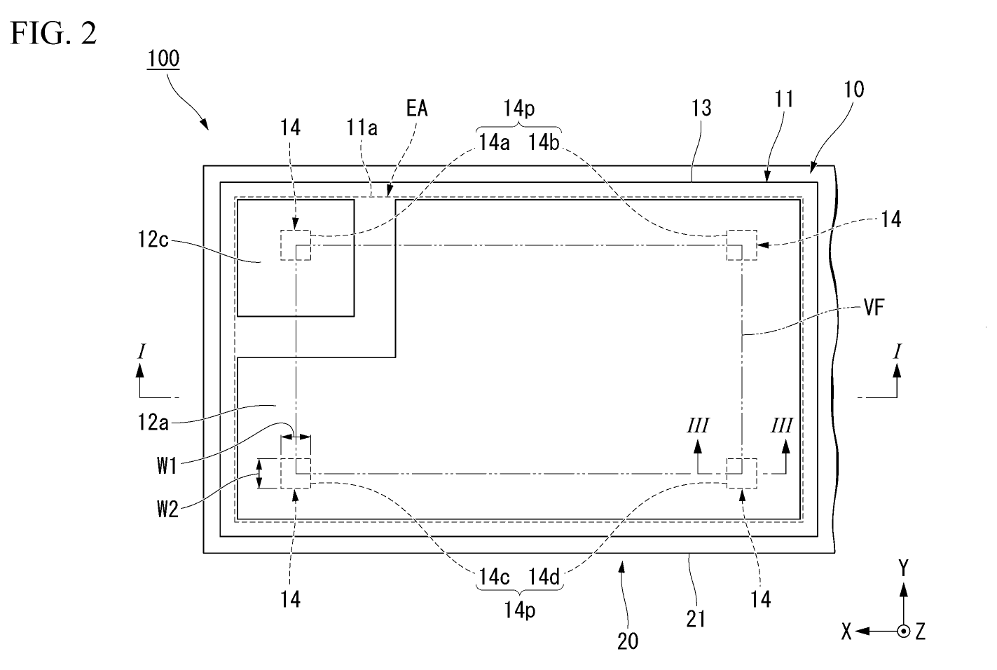

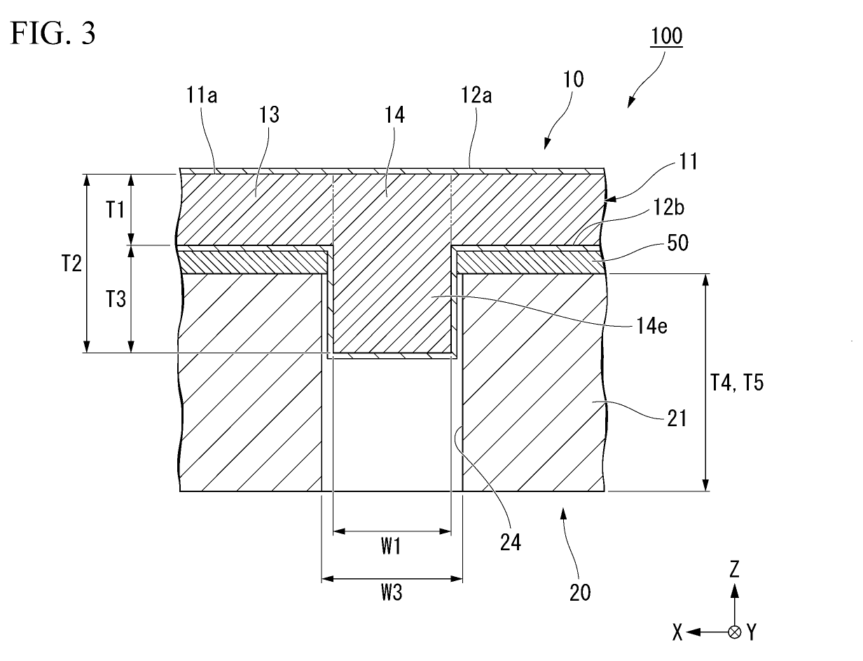

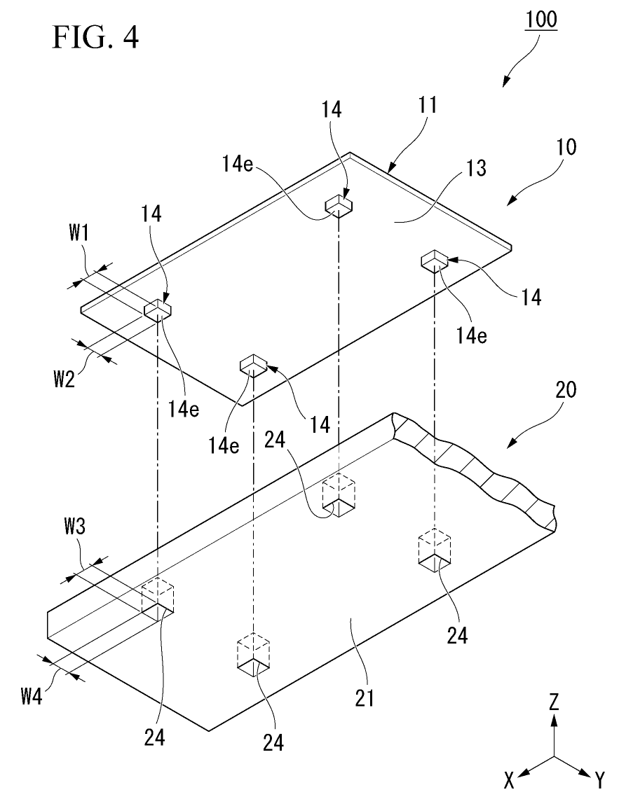

FIG. 1 is a cross-sectional view showing a semiconductor device 100 according to a first embodiment, including a cross section taken along I-I of FIG. 2. FIG. 2 is a view of a part of the semiconductor device 100 according to the first embodiment as viewed from above. FIG. 3 is a cross-sectional view showing a part of the semiconductor device 100 according to the first embodiment, the cross section being taken along III-III of FIG. 2. FIG. 4 is an exploded perspective view showing a part of the semiconductor device 100 according to the first embodiment. A second conductive member 30, a resin portion 40, and a third conductive member which will be described below are not shown in FIG. 2. A second electrode 12b of a semiconductor chip 10 which will be described below is not shown in FIG. 4. As shown in FIG. 1, the semiconductor device 100 includes the semiconductor chip 10, a first conductive member 20, the second conductive member 30, and the resin part 40.

The semiconductor chip 10 is a transistor having a vertical structure. In the first embodiment, the semiconductor chip 10 is a field-effect transistor (FET). The semiconductor chip 10 is, for example, a metal-oxide-semiconductor field-effect transistor (MOSFET). As shown in FIGS. 1 and 2, the semiconductor chip 10 is a plate-like chip whose dimension in the thickness direction Z is smaller than dimensions in the first direction X and the second direction Y. As shown in FIG. 1, the semiconductor chip 10 is located above the first conductive member 20. The semiconductor chip 10 has a semiconductor substrate 11, a first electrode 12a, and the second electrode 12b. As shown in FIG. 2, the semiconductor chip 10 has a third electrode 12c.

The semiconductor substrate 11 has a plate shape in which a plate surface faces the thickness direction Z. In the first embodiment, the semiconductor substrate 11 has a rectangular shape having a pair of sides extending in the first direction X and a pair of sides extending in the second direction Y, as viewed in the thickness direction Z. In the example of FIG. 2, the dimension of the semiconductor substrate 11 in the first direction X is greater than the dimension of the semiconductor substrate 11 in the second direction Y. The dimension of the semiconductor substrate 11 in the first direction X may be the same as the dimension of the semiconductor substrate 11 in the second direction Y, or may be smaller than the dimension of the semiconductor substrate 11 in the second direction Y.

The first electrode 12a and the third electrode 12c are formed on a surface on the upper side of the semiconductor substrate 11. In the first embodiment, the first electrode 12a is a source electrode. In the first embodiment, the third electrode 12c is a gate electrode. In the example of FIG. 2, as viewed in the thickness direction Z, an area of the first electrode 12a is larger than an area of the third electrode 12c. A size relationship between the area of the first electrode 12a when viewed in the thickness direction Z and the area of the third electrode 12c when viewed in the thickness direction Z is not particularly limited. As shown in FIG. 1, the second electrode 12b is formed on a surface on the lower side of the semiconductor substrate 11. In the first embodiment, the second electrode 12b is a drain electrode. In the first embodiment, the second electrode 12b is formed over the entire surface on the lower side of the semiconductor substrate 11. The first electrode 12a, the second electrode 12b, and the third electrode 12c are formed of, for example, a metal material.

The material forming the semiconductor substrate 11 includes a semiconductor material such as silicon (Si). As shown in FIG. 2, the semiconductor substrate 11 has a semiconductor element 11a. In the first embodiment, the semiconductor element 11a is an element that functions as a transistor. The semiconductor element 11a has, for example, a portion formed by adding impurities to a semiconductor material such as silicon (Si), and an insulating film formed of polyimide or the like. In the first embodiment, the semiconductor element 11a may have any structure as long as it functions as a transistor. As shown in FIG. 3, a part of the semiconductor element 11a is located between the first electrode 12a and the second electrode 12b in the thickness direction Z. The other part of the semiconductor element 11a includes a portion located between the third electrode 12c and the second electrode 12b. In FIG. 2, a region EA of the semiconductor substrate 11 on which the semiconductor element 11a is formed is indicated by a rectangular broken line. In the first embodiment, the entire first electrode 12a and the entire third electrode 12c are located inside the region EA as viewed in the thickness direction Z. When a current flows from one of the first electrode 12a and the second electrode 12b to the other, the current flows from one of the first electrode 12a and the second electrode 12b to the other via the semiconductor element 11a.

As shown in FIG. 4, the semiconductor substrate 11 has a first portion 13 and a plurality of second portions 14. The first portion 13 and the plurality of second portions 14 are disposed at positions different from each other as viewed in the thickness direction Z. In FIG. 3 and the like, the boundary between the first portion 13 and the second portion 14 is indicated by a two-dot chain line. The first portion 13 includes an outer peripheral edge of the semiconductor substrate 11 as viewed in the thickness direction Z. In the first embodiment, the first portion 13 is the entire portion of the semiconductor substrate 11 excluding the plurality of second portions 14. As shown in FIG. 3, the second electrode 12b is formed on a surface on the lower side of the first portion 13. The surface on the lower side of the first portion 13 is a part of the surface on the lower side of the semiconductor substrate 11. A surface on the upper side of the first portion 13 is a part of the surface on the upper side of the semiconductor substrate 11.

The plurality of second portions 14 are disposed at positions different from the first portion 13 as viewed in the thickness direction Z. In the present embodiment, the plurality of second portions 14 are disposed adjacent to the first portion 13 as viewed in the thickness direction Z. The plurality of second portions 14 are disposed away from the outer peripheral edge of the semiconductor substrate 11 as viewed in the thickness direction Z. A surface on the lower side of each of the second portions 14 is a part of the surface on the lower side of the semiconductor substrate 11. A surface on the upper side of each of the second portions 14 is a part of the surface on the upper side of the semiconductor substrate 11. As shown in FIG. 3, a dimension T2 of each of the plurality of second portions 14 in the thickness direction Z is greater than a dimension T1 of the first portion 13 in the thickness direction Z. In the first embodiment, the dimension T2 is equal to or greater than twice and equal to or less than five times the dimension T1. The dimension T2 is, for example, about 30 μm (micrometers) to 250 μm. The dimension T1 is, for example, about 10 μm to 50 μm. In the first embodiment, each second portion 14 protrudes further toward the lower side than the first portion 13. Each second portion 14 has a protrusion 14e located below the first portion 13. The protrusion 14e is a portion of the second portion 14 that protrudes further toward the lower side than the surface on the lower side of the first portion 13. A dimension T3 of the protrusion 14e in the thickness direction Z is greater than a dimension in the thickness direction Z of a portion of the second portion 14 other than the protrusion 14e. The dimension in the thickness direction Z of the portion of the second portion 14 other than the protrusion 14e is equal to the dimension T1 of the first portion 13 in the thickness direction Z. A surface on the lower side of the protrusion 14e forms a part of the surface on the lower side of the semiconductor substrate 11. The second electrode 12b is formed on the surface on the lower side of the protrusion 14e and side surfaces of the protrusion 14e. The side surfaces of the protrusion 14e include both side surfaces of the protrusion 14e in the first direction X and both side surfaces of the protrusion 14e in the second direction Y.

As shown in FIG. 2, in the first embodiment, the plurality of second portions 14 are disposed away from each other. In the first embodiment, the number of the plurality of second portions 14 is four. The plurality of second portions 14 include a second portion 14a, a second portion 14b, a second portion 14c, and a second portion 14d. The second portion 14a and the second portion 14b are located further toward one side in the second direction Y (+Y side) than the second portion 14c and the second portion 14d. The second portion 14a and the second portion 14c are located further toward one side in the first direction X (+X side) than the second portion 14b and the second portion 14d. The four second portions 14a to 14d are disposed at respective corners of a rectangular virtual frame VF shown virtually in FIG. 2, as viewed in the thickness direction Z. The virtual frame VF is a rectangular frame having a pair of sides extending in the first direction X and a pair of sides extending in the second direction Y.

The two second portions 14, including the second portion 14a and the second portion 14b, constitute a pair 14p of the second portions 14 that are arranged side by side with a space therebetween in the first direction X. The two second portions 14, including the second portion 14c and the second portion 14d, constitute a pair 14p of the second portions 14 that are arranged side by side with a space therebetween in the first direction X. In other words, in the first embodiment, the plurality of second portions 14 include two pairs 14p of the second portions 14. The pair 14p of two second portions 14 are arranged side by side in the second direction Y. The second portion 14a and the second portion 14c are arranged side by side with a space therebetween in the second direction Y. The second portion 14b and the second portion 14d are arranged side by side with a space therebetween in the second direction Y. In addition, the plurality of second portions 14 may include three or more pairs 14p of the second portions 14.

A dimension W1 of each second portion 14 in the first direction X is greater than 0.5 times and less than twice a dimension W2 of each second portion 14 in the second direction Y. It is more preferable that the dimension W1 be, for example, equal to or greater than 0.8 times and equal to or less than 1.2 times the dimension W2. The dimensions W1 and W2 may be the same as or different from each other. The dimension W1 is, for example, 50 μm to 200 μm. The dimension W2 is, for example, 50 μm to 200 μm.

A shape of each second portion 14 as viewed in the thickness direction Z is not particularly limited. The shape of each second portion 14 as viewed in the thickness direction Z may be a quadrilateral shape, or may be a quadrilateral shape with rounded corners. The shape of each second portion 14 as viewed in the thickness direction Z may be a quadrilateral shape with C-chamfered corners, that is, an octagonal shape. The shape of each second portion 14 as viewed in the thickness direction Z may be a polygonal shape other than a quadrilateral shape, or may be a polygonal shape, other than a quadrilateral shape, with chamfered corners. The shape of each second portion 14 as viewed in the thickness direction Z may be a circular shape, or may be an elliptical shape.

As viewed in the thickness direction Z, an area of each second portion 14 is smaller than the area of the first portion 13. As viewed in the thickness direction Z, a total value of the areas of the plurality of second portions 14 is smaller than the area of the first portion 13. In the first embodiment, the total value of the areas of the plurality of second portions 14 when viewed in the thickness direction Z is a total value of areas of the second portions 14a to 14d when viewed in the thickness direction Z. As viewed in the thickness direction Z, a total value of the areas of the plurality of second portions 14 is less than or equal to one tenth of the area of the first portion 13.

In the first embodiment, the plurality of second portions 14 are located, as viewed in the thickness direction Z, inside the region EA of the semiconductor substrate 11 on which the semiconductor element 11a is formed. In other words, the plurality of second portions 14a, 14b, 14c, and 14d are disposed at positions overlapping the area EA as viewed in the thickness direction Z. In the first embodiment, the expression “the second portions 14 are located inside the region EA as viewed in the thickness direction Z” means that the second portions 14 are located inside the rectangular broken line indicating the region EA in FIG. 2. In the first embodiment, the semiconductor element 11a has a portion formed in the first portion 13 and portions formed in the plurality of second portions 14. The second portions 14b, 14c, and 14d are disposed at portions overlapping the first electrode 12a as viewed in the thickness direction Z. The second portion 14a is disposed at a position overlapping the third electrode 12c as viewed in the thickness direction Z. One or more second portions 14 may be disposed at positions that do not overlap both the first electrode 12a and the third electrode 12c as viewed in the thickness direction Z. None of the plurality of second portions 14 may overlap the third electrode 12c as viewed in the thickness direction Z. None of the plurality of second portions 14 may overlap the first electrode 12a as viewed in the thickness direction Z.

As shown in FIG. 1, the first conductive member 20 is a conductive member to which the semiconductor chip 10 is fixed. The first conductive member 20 is electrically connected to the semiconductor chip 10. The first conductive member 20 is located below the semiconductor chip 10. The first conductive member 20 is conductive. The first conductive member 20 is made of metal. The metal forming the first conductive member 20 is, for example, copper (Cu) or an alloy containing copper (Cu). The material forming the first conductive member 20 is not particularly limited as long as it is conductive. In the first embodiment, the first conductive member 20 has a plate shape. The first conductive member 20 is formed by subjecting a plate-like member to press working. A surface on the upper side of the first conductive member 20 is electrically joined to a surface on the lower side of the second electrode 12b via a bonding material 50. Accordingly, the first conductive member 20 is electrically connected to the second electrode 12b. In the first embodiment, the bonding material 50 is solder. The bonding material 50 may be a silver paste or the like.

The first conductive member 20 has a first portion to be connected 21, a first bent portion 22, and a first terminal portion 23. The first portion to be connected 21 has a plate shape in which a plate surface faces the thickness direction Z. The semiconductor chip 10 is fixed to a surface on the upper side of the first portion to be connected 21 via the bonding material 50. The first portion to be connected 21 is electrically joined to the second electrode 12b formed on the surface on the lower side of the first portion 13 via the bonding material 50. In other words, the portion of the second electrode 12b which is formed on the surface on the lower side of the first portion 13 is electrically joined to the surface on the upper side of the first conductive member 20 via the bonding material 50. As shown in FIG. 3, a dimension T4 of the first portion to be connected 21 in the thickness direction Z is greater than the dimension T3 of the protrusion 14e in the thickness direction Z. The dimension T4 of the first portion to be connected 21 in the thickness direction Z is greater than the dimension T2 of each of the second portions 14 in the thickness direction Z. The dimension T4 is, for example, about 200 μm to 1,000 μm.

As shown in FIG. 1, the first bent portion 22 is bent downward from an end portion on the other side (-X side) in the first direction X of the first portion to be connected 21. The first bent portion 22 connects the first portion to be connected 21 to the first terminal portion 23. The first terminal portion 23 extends to the other side (-X side) in the first direction X from an end portion on the lower side of the first bent portion 22. The first terminal portion 23 is located below the first portion to be connected 21. The shape of the first conductive member 20 is not particularly limited.

As shown in FIG. 4, the first conductive member 20 has a plurality of hole portions (holes) 24 formed therein. The plurality of hole portions 24 are recessed downward from the surface on the upper side of the first conductive member 20. In the first embodiment, the plurality of hole portions 24 are formed in the first portion to be connected 21. The plurality of hole portions 24 are recessed downward from the surface on the upper side of the first portion to be connected 21. In the first embodiment, each hole portion 24 is a through-hole penetrating the first conductive member 20 in the thickness direction Z. Each hole portion 24 penetrates the first portion to be connected 21 in the thickness direction Z. Each hole portion 24 does not necessarily penetrate the first conductive member 20 in the thickness direction Z. In this case, each hole portion 24 is a hole which is recessed downward from the surface on the upper side of the first conductive member 20 and has a bottom portion on a lower side. As shown in FIG. 3, a dimension T5 of each hole portion 24 in the thickness direction Z is greater than the dimension T3 of the protrusion 14e in the thickness direction Z. The dimension T5 of each hole portion 24 in the thickness direction Z is greater than the dimension T2 of each second portion 14 in the thickness direction Z. In the first embodiment, the dimension T5 of each hole portion 24 in the thickness direction Z is equal to the dimension T4 of the first portion to be connected 21 in the thickness direction Z.

As shown in FIG. 4, the number of the plurality of hole portions 24 is the same as the number of the plurality of second portions 14. In other words, in the first embodiment, the number of the plurality of hole portions 24 is four. Each hole portion 24 is disposed at a position overlapping each second portion 14 as viewed in the thickness direction Z. As shown in FIG. 3, a part of each second portion 14 is located inside each hole portion 24. In the first embodiment, the lower portion of the protrusion 14e of each second portion 14 is located inside each hole portion 24.

A dimension W3 of each hole portion 24 in the first direction X is greater than the dimension W1 of each second portion 14 in the first direction X. As shown in FIG. 4, a dimension W4 of each hole portion 24 in the second direction Y is greater than the dimension W2 of each second portion 14 in the second direction Y. The dimension W3 of each hole portion 24 in the first direction X and the dimension W4 of each hole portion 24 in the second direction Y may be the same as or different from each other. The difference between the dimension W3 of each hole portion 24 in the first direction X and the dimension W1 of each second portion 14 in the first direction X is, for example, about 20 μm to 50 μm. The difference between the dimension W4 of each hole portion 24 in the second direction Y and the dimension W2 of each second portion 14 in the second direction Y is also, for example, about 20 μm to 50 μm. At least a part of an outer surface of a portion of each second portion 14 which is located inside each hole portion 24 is disposed away from the inner surface of each hole portion 24. The distance between the outer surface of each second portion 14 and the inner surface of each hole portion 24 is, for example, 50 μm or less. The distance between the outer surface of each second portion 14 and the inner surface of each hole portion 24 is preferably, for example, 25 μm or less. The size of each hole portion 24 as viewed in the thickness direction Z is not particularly limited as long as each protrusion 14e of each second portion 14 can be inserted therein. The dimension W3 of each hole portion 24 in the first direction X is, for example, 70 μm to 250 μm. The dimension W4 of each hole portion 24 in the second direction Y is, for example, 70 μm to 250 μm.

A shape of each hole portion 24 as viewed in the thickness direction Z is not particularly limited. The shape of each hole portion 24 as viewed in the thickness direction Z may be the same as the shape of each second portion 14 as viewed in the thickness direction Z, or may be different from the shape of each second portion 14 as viewed in the thickness direction Z. The shape of each hole portion 24 as viewed in the thickness direction Z may be a quadrilateral shape, or may be a quadrilateral shape with rounded corners. The shape of each hole portion 24 as viewed in the thickness direction Z may be a quadrilateral shape with C-chamfered corners, that is, an octagonal shape. The shape of each hole portion 24 as viewed in the thickness direction Z may be a polygonal shape other than a quadrilateral shape, or may be a polygonal shape, other than a quadrilateral shape, with chamfered corners. The shape of each hole portion 24 as viewed in the thickness direction Z may be a circular shape, or may be an elliptical shape.

As shown in FIG. 1, the second conductive member 30 is located away from the first conductive member 20 on one side in the first direction X (+X side). The second conductive member 30 is conductive. The second conductive member 30 is made of metal. The metal forming the second conductive member 30 is, for example, copper (Cu) or an alloy containing copper (Cu). The material forming the second conductive member 30 is not particularly limited as long as it is conductive. In the first embodiment, the second conductive member 30 has a plate shape. The second conductive member 30 is formed by subjecting a plate-like member to press working.

The second conductive member 30 has a second portion to be connected 31, a second bent portion 32, and a second terminal portion 33. The second portion to be connected 31 has a plate shape in which a plate surface faces the thickness direction Z. The second portion to be connected 31 is disposed at the same position as the first portion to be connected 21 in the thickness direction Z. A surface on the upper side of the second portion to be connected 31 and a surface on the upper side of the first electrode 12a of the semiconductor chip 10 are electrically connected via a bonding wire 60. Accordingly, the second conductive member 30 is electrically connected to the first electrode 12a. The bonding wire 60 is made of metal. The material constituting the bonding wire 60 is, for example, gold (Au), silver (Ag), copper (Cu), aluminum (Al), or the like. The second bent portion 32 is bent downward from an end portion on one side (+X side) in the first direction X of the second portion to be connected 31. The second bent portion 32 connects the second portion to be connected 31 to the second terminal portion 33. The second terminal portion 33 extends to one side (+X side) in the first direction X from an end portion on the lower side of the second bent portion 32. The second terminal portion 33 is located below the second portion to be connected 31. The second terminal portion 33 is disposed at the same position as the first terminal portion 23 in the thickness direction Z. The shape of the second conductive member 30 is not particularly limited.

Although not shown in the drawing, the semiconductor device 100 includes a third conductive member that is electrically connected to the third electrode 12c. The third conductive member is electrically connected to the third electrode 12c via, for example, a bonding wire different from the bonding wire 60. The third conductive member has, for example, the same shape as the second conductive member 30. In other words, the third conductive member has, for example, a third portion to be connected corresponding to the second portion to be connected 31, a third bent portion corresponding to the second bent portion 32, and a third terminal portion corresponding to the second terminal portion 33. The shape of the third conductive member is not particularly limited.

The resin portion 40 covers at least a part of each of the semiconductor chip 10, the first conductive member 20, the second conductive member 30, and the third conductive member (not shown). The semiconductor chip 10, the first portion to be connected 21, and the second portion to be connected 31 are embedded inside the resin portion 40. The first bent portion 22, the first terminal portion 23, the second bent portion 32, and the second terminal portion 33 are exposed outside the resin portion 40. The portion of the third conductive member (not shown) to which the bonding wire is connected is embedded inside the resin portion 40. The bent portion and terminal portion of the third conductive member (not shown) are exposed outside the resin portion 40. The resin portion 40 is formed of, for example, epoxy resin. The resin forming the resin portion 40 may be a resin other than the epoxy resin.

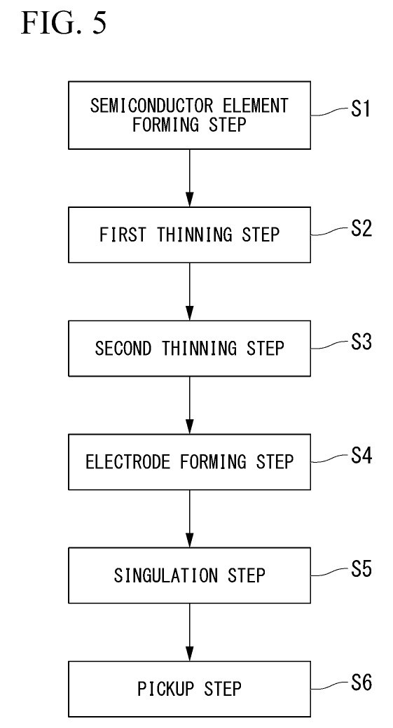

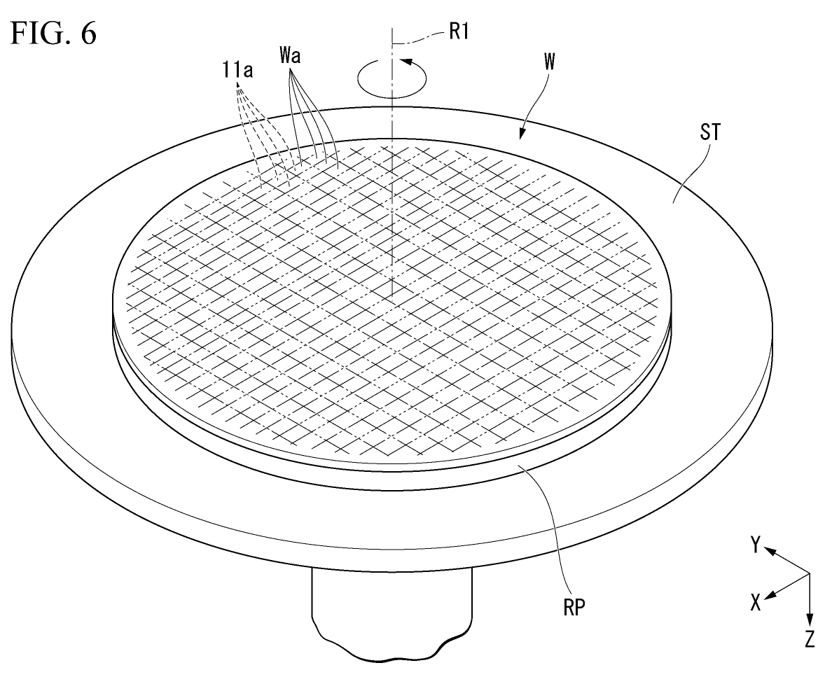

Next, a method for manufacturing the semiconductor device 100 will be described. FIG. 5 is a flowchart showing a part of a procedure of the method for manufacturing the semiconductor device 100. The flowchart shown in FIG. 5 shows a procedure of a method for manufacturing the semiconductor chip 10. FIG. 6 is a perspective view showing a part of the procedure of the method for manufacturing the semiconductor device 100. As shown in FIG. 5, the method for manufacturing the semiconductor device 100 includes a semiconductor element forming step S1, a first thinning step S2, a second thinning step S3, an electrode forming step S4, a singulation step S5, and a pickup step S6.

The semiconductor element forming step S1 is a step of forming a plurality of the semiconductor elements 11a on a wafer W. In the semiconductor element forming step S1, as shown in FIG. 6, the plurality of semiconductor elements 11a are formed in a matrix shape aligned in the first direction X and the second direction Y on a surface of the wafer W on one side (+Z side) in the thickness direction Z. Each region of the wafer W on which the plurality of semiconductor elements 11a are formed is a chip region Wa to be processed into a semiconductor chip 10. A plurality of chip regions Wa are arranged in a matrix shape aligned in the first direction X and the second direction Y. In the first embodiment, in the semiconductor element forming step S1, the first electrode 12a and the third electrode 12c are formed in each chip region Wa. The first electrode 12a and the third electrode 12c may be formed in a step subsequent to the semiconductor element forming step S1.

The first thinning step S2 is a step of thinning the wafer W. In the first thinning step S2, the wafer W is entirely thinned by being ground by a grinding wheel (not shown) from a surface on the side (-Z side) opposite to the side on which the semiconductor elements 11a are formed. As shown in FIG. 6, during grinding with the grinding wheel, the wafer W is placed on a stage ST in a state where a reinforcing plate RP is attached to a surface on the side (+Z side) on which the plurality of semiconductor elements 11a are formed. The wafer W to which the reinforcing plate RP is attached is placed on the stage ST in a position in which the reinforcing plate RP is located on the stage ST side. The stage ST is rotatable about a first rotation axis R1 extending in the vertical direction. The wafer W is ground by the grinding wheel while rotating about the first rotation axis R1 together with the stage ST. After being ground by the grinding wheel, the ground surface of the wafer W is subjected to, for example, wet etching. Accordingly, a damaged layer that has been generated on the surface of the wafer W due to grinding by the grinding wheel is removed.

As a result of the above, the first thinning step S2 is completed, and the wafer W is thinned. As an example, by performing the first thinning step S2, a dimension of the wafer W in the thickness direction Z becomes 60 μm. In this case, for example, in the first thinning step S2, the wafer W is ground by the grinding wheel to a thickness of 65 μm, and then further removed by 5 μm through wet etching to a thickness of 60 μm.

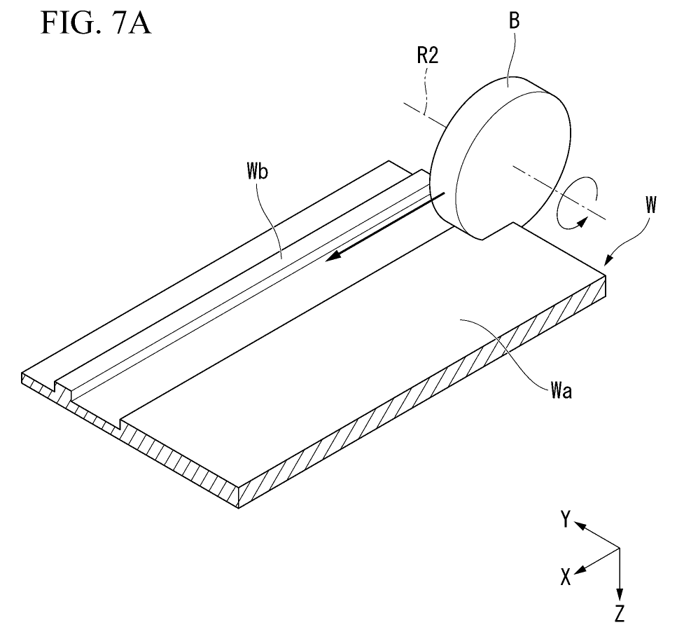

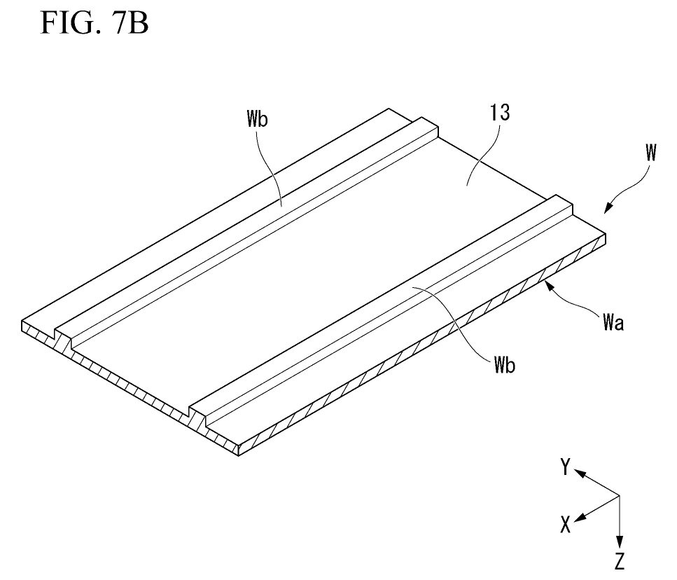

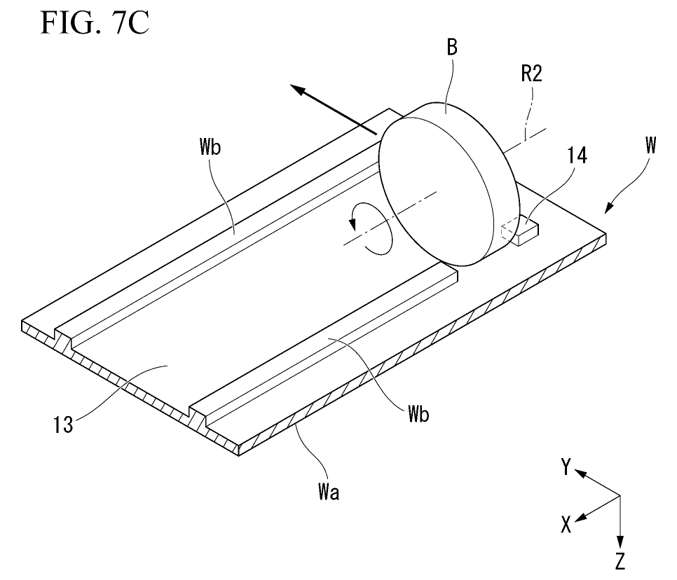

The second thinning step S3 is a step of further thinning the wafer W while leaving portions that will become the plurality of second portions 14. FIG. 7A is a perspective view showing a part of the procedure of the second thinning step S3. FIG. 7B is a perspective view showing another part of the procedure of the second thinning step S3. FIG. 7C is a perspective view showing still another part of the procedure of the second thinning step S3. In FIGS. 7A to 7C, only one chip region Wa of the wafer W is shown.

As shown in FIG. 7A, in the second thinning step S3, the wafer W is ground by a dicing blade B from the surface on the side (-Z side) opposite to the side on which the semiconductor elements 11a are formed. The dicing blade B is a grindstone containing diamond abrasive grains. The dicing blade B is rotatable about a second rotation axis R2 extending in a direction orthogonal to the vertical direction. The dicing blade B is movable in the axial direction of the second rotation axis R2, in a direction orthogonal to both the axial direction and vertical direction of the second rotation axis R2, and in the vertical direction. A dimension of the dicing blade B in the axial direction of the second rotation axis R2 is, for example, 3 mm. When being ground by the dicing blade B, the wafer W is placed on the stage ST in the same manner as in the first thinning step S2.

First, the rotational position of the stage ST about the first axis of rotation R1 is fixed at a position where the second rotation axis R2 is in a position extending in the second direction Y of the wafer W. In this state, as shown in FIG. 7A, the position of the dicing blade B in the thickness direction Z is adjusted to a position capable of grinding a desired amount, and the dicing blade B is moved in the first direction X while rotating about the second rotation axis R2. Accordingly, a part of the wafer W is ground by the dicing blade B. After grinding the wafer W from one end to the other end in the first direction X, the dicing blade B is moved in the axial direction (second direction Y) of the second rotation axis R2 and then moved in the first direction X while rotating again about the second rotation axis R2. The operation of moving the dicing blade B in the first direction X to grind the wafer W is performed on the entire wafer W in the second direction Y, except for the positions in the second direction Y of portions of each chip region Wa that will become the plurality of second portions 14.

When the operation of moving the dicing blade B in the first direction X to grind the wafer W is completed, the wafer W is in the state shown in FIG. 7B. In each chip region Wa of the wafer W shown in FIG. 7B, two thick portions Wb are formed which are left thick without being ground by the operation of moving the dicing blade B in the first direction X. In each chip region Wa, the two thick portions Wb extend from one end to the other end in the first direction X. Although not shown in the drawing, the two thick portions Wb formed in one of the two chip regions Wa adjacent to each other in the first direction X, and the two thick portions Wb formed in the other of the two chip regions Wa adjacent to each other in the first direction X, are each connected in the first direction X.

After the operation of moving the dicing blade B in the first direction X to grind the wafer W is completed, the stage ST is rotated 90° about the first rotation axis R1. Accordingly, the rotational position of the stage ST about the first axis of rotation R1 is fixed at a position where the second rotation axis R2 is in a position extending in the first direction X of the wafer W. In this state, as shown in FIG. 7C, the dicing blade B is moved in the second direction Y while rotating about the second rotation axis R2. In FIGS. 7A and 7C, the stage ST has rotated 90° about the first rotation axis R1, and therefore the relative movement direction of the dicing blade B with respect to the wafer W has changed. However, in FIGS. 7A and 7C, the absolute direction in which the dicing blade B is moved when grinding the wafer W is not changed. The dicing blade B is moved in the second direction Y while rotating about the second rotation axis R2, thereby grinding a part of the plurality of thick portions Wb. After grinding the wafer W from one end to the other end in the second direction Y, the dicing blade B is moved in the axial direction (first direction X) of the second rotation axis R2 and then moved in the second direction Y while rotating again about the second rotation axis R2. The operation of moving the dicing blade B in the second direction Y to grind the wafer W is performed on the entire wafer W, except for portions of each thick portion Wb that will become the second portions 14. Accordingly, a first portion 13 and a plurality of second portions 14 are formed in each chip region Wa of the wafer W. In this manner, in the method for manufacturing the semiconductor device 100, thinning the wafer W includes forming the first portion 13 and the plurality of second portions 14 in each chip region Wa. In addition, in the method for manufacturing the semiconductor device 100, the formation of the first portion 13 and the plurality of second portions 14 in each chip region Wa is performed by blade dicing using the dicing blade B.

After grinding in the first direction X and the second direction Y by the dicing blade B is completed, the ground surface of the wafer W is subjected to, for example, plasma etching. Accordingly, a damaged layer that has been generated on the surface of the wafer W due to grinding by the dicing blade B is removed.

As a result of the above, the second thinning step S3 is completed, and the wafer W is further thinned. As an example, by performing the second thinning step S3, the dimension of the wafer W in the thickness direction Z becomes 20 μm in each of the first portions 13 and 55 μm in each of the second portions 14. In this case, for example, in the second thinning step S3, the portions of the wafer W that will become each first portion 13 are ground to a thickness of 25 μm by the dicing blade B, and then further removed by 5 μm through plasma etching to a thickness of 20 μm. For example, in the second thinning step S3, the portions of the wafer W that will become each second portion 14 are left unground by the dicing blade B at a thickness of 60 μm, and are then removed by 5 μm through plasma etching to a thickness of 55 μm. As an example, the dimension W1 in the first direction X of each second portion 14 formed in the second thinning step S3 is 100 μm. The dimension W2 in the second direction Y of each second portion 14 formed in the second thinning step S3 is 100 μm.

In the first thinning step S2 and the second thinning step S3, any type of etching may be employed for removing the damaged layer as long as it can remove the damaged layer. For example, in the second thinning step S3, the damaged layer may be removed by wet etching.

The electrode forming step S4 is a step of forming the second electrode 12b on the surface of the wafer W that is on the side (-Z side) that has been ground in the first thinning step S2 and the second thinning step S3. The second electrode 12b is formed on the entire ground surface of the wafer W by, for example, a sputtering method. At this time, the second electrode 12b is also formed on the entire outer surface of the protrusion 14e of each second portion 14.

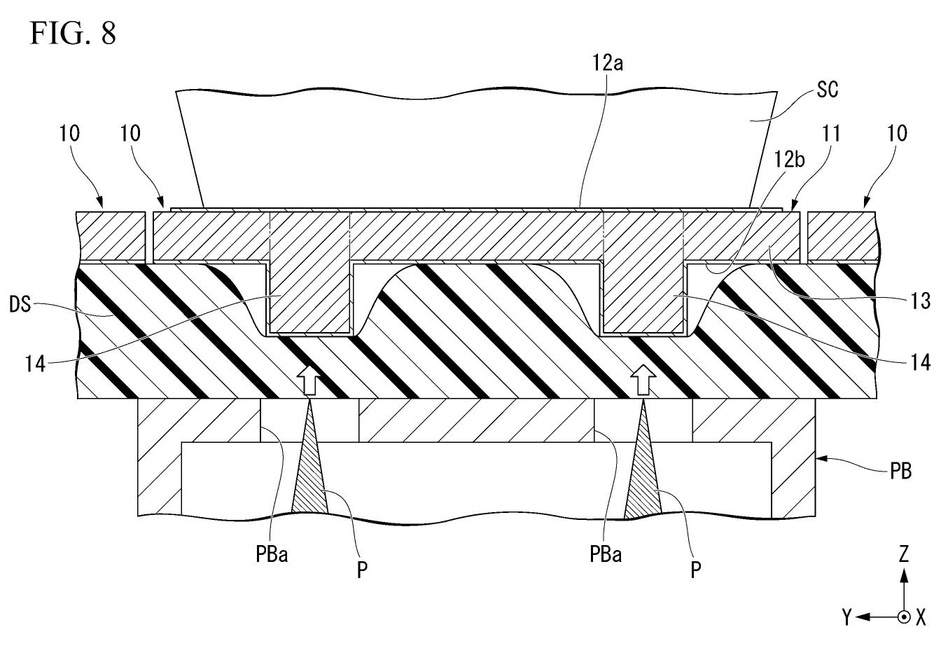

The singulation step S5 is a step of dividing the wafer W into a plurality of semiconductor chips 10. In the singulation step S5, the wafer W is fixed to an adhesive tape DS as shown in FIG. 8. FIG. 8 is a cross-sectional view showing a part of the procedure of the pickup step S6. The adhesive tape DS is a dicing sheet. The wafer W attached to the adhesive tape DS is cut between the plurality of chip regions Wa and divided into a plurality of semiconductor chips 10. At this time, the divided plurality of semiconductor chips 10 remain attached to the adhesive tape DS. In the singulation step S5, the wafer W is cut by, for example, another dicing blade having a smaller width in the axial direction of the second rotation axis R2 than the dicing blade B described above.

The pickup step S6 is a step of separating the plurality of semiconductor chips 10 attached to the adhesive tape DS from the adhesive tape DS. As shown in FIG. 8, in the pickup step S6, each semiconductor chip 10 is sucked and lifted by a suction collet SC, and is also pushed up by a plurality of pins P to be separated from the adhesive tape DS. The plurality of pins P push up each semiconductor chip 10 upward in the vertical direction from the lower side of the adhesive tape DS in the vertical direction. The number of the plurality of pins P is the same as the number of the plurality of second portions 14. In other words, in the first embodiment, each semiconductor chip 10 is pushed up by four pins P. The plurality of pins P respectively push up the plurality of second portions 14 from a lower side in the vertical direction via the adhesive tape DS. In other words, separating each semiconductor chip 10 from the adhesive tape DS includes pushing up each semiconductor chip 10 in the thickness direction Z by the pins P located at positions overlapping the second portions 14 as viewed in the thickness direction Z. The plurality of pins P pass in the vertical direction through a plurality of through holes PBa formed in a support member PB that supports the adhesive tape DS from the lower side in the vertical direction, and push up the plurality of second portions 14.

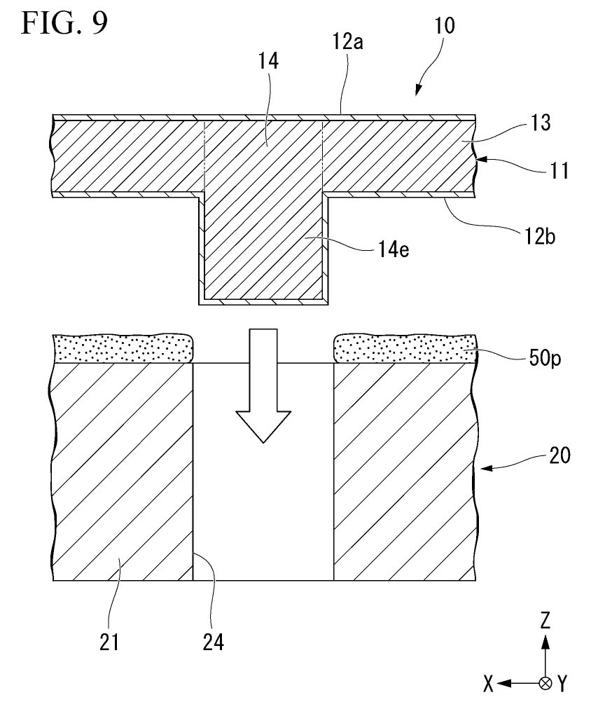

The method for manufacturing the semiconductor device 100 further includes a step of fixing the semiconductor chip 10 to the first conductive member 20. FIG. 9 is a cross-sectional view showing a part of the procedure of the step of fixing the semiconductor chip 10 to the first conductive member 20. As shown in FIG. 9, the semiconductor chip 10 separated from the adhesive tape DS is brought close to the first conductive member 20 from above. At this time, a paste material 50p containing a powdered bonding material 50 is applied to the surface on the upper side of the first portion to be connected 21 of the first conductive member 20. In the first embodiment, the paste material 50p is a cream solder containing powdered solder and a binder such as flux. In the example of FIG. 9, the paste material 50p is not attached to the inner surface of the hole portion 24, but the paste material 50p may be attached to the inner surface of the hole portion 24 as well. As an example, the dimension W3 of the hole portion 24 in the first direction X and the dimension W4 of the hole portion 24 in the second direction Y are 120 μm. The semiconductor chip 10 is disposed above the first conductive member 20 with the applied paste material 50p interposed therebetween. At this time, the protrusion 14e of each second portion 14 is inserted into each hole portion 24. In this state, the semiconductor chip 10 and the first conductive member 20 are heated, and the bonding material 50 contained in the paste material 50p is melted. The first conductive member 20 and the second electrode 12b are joined to each other by curing the molten bonding material 50 after it adheres to the surface on the upper side of the first conductive member 20 and the second electrode 12b. The binder contained in each paste material 50p is vaporized by heat when the bonding material 50 is melted.

After the semiconductor chip 10 and the first conductive member 20 are fixed, the second conductive member 30 and the first electrode 12a are connected to each other by wire bonding, and the third conductive member (not shown) and the third electrode 12c are connected to each other by wire bonding. Thereafter, the semiconductor chip 10, the first conductive member 20, the second conductive member 30, and the third conductive member are placed in a mold, and a resin is injected into the mold, thereby forming the resin part 40. Before the resin portion 40 is formed, each conductive member is in a state in which, for example, each of the bent portions described above is not yet formed. After the resin portion 40 is formed, a part of a portion of each conductive member that is exposed outside the resin portion 40 is bent, thereby forming each bent portion in each conductive member. As a result of the above, the semiconductor device 100 is manufactured. Each conductive member may be in a state where a part thereof is bent to form each bent portion before the resin portion 40 is formed. Each conductive member may have a shape that does not have a bent portion that has been bent.

According to the first embodiment, the semiconductor device 100 includes the semiconductor chip 10 fixed to the first conductive member 20. The semiconductor chip 10 has the semiconductor substrate 11 on which the semiconductor elements 11a are formed. The semiconductor chip 10 has the first electrode 12a formed on the surface of the semiconductor substrate 11 on the upper side (+Z side) in the thickness direction Z, and the second electrode 12b formed on the surface of the semiconductor substrate 11 on the lower side (-Z side) in the thickness direction Z. The semiconductor substrate 11 has the first portion 13 including an outer peripheral edge of the semiconductor substrate 11 as viewed in the thickness direction Z of the semiconductor substrate 11 and the second portions 14 disposed away from the outer peripheral edge of the semiconductor substrate 11 as viewed in the thickness direction Z of the semiconductor substrate 11. The second portions 14 are disposed at positions different from the first portion 13 as viewed in the thickness direction Z. The surface on the upper side of the first portion 13 is a part of the surface on the upper side of the semiconductor substrate 11. The surface on the upper side of each of the second portions 14 is another part of the surface on the upper side of the semiconductor substrate 11. The surface on the lower side of the first portion 13 is a part of the surface on the lower side of the semiconductor substrate 11. The surface on the lower side of each of the second portions 14 is another part of the surface on the lower side of the semiconductor substrate 11. The first conductive member 20 is disposed below the semiconductor chip 10. A portion of the second electrode 12b formed on the surface on the lower side of the first portion 13 is electrically joined to the first conductive member 20 via the bonding material 50. The dimension T2 of each of the second portions 14 in the thickness direction Z is greater than the dimension T1 of the first portion 13 in the thickness direction Z. The second portions 14 protrude further toward the lower side than the first portion 13. Therefore, the strength of the second portions 14 can be made greater than the strength of the first portion 13. Accordingly, when separating the semiconductor chip 10 from the adhesive tape DS as described above, the second portions 14, which are thicker than the first portion 13, can be pushed up from below by the pins P, thereby preventing the semiconductor substrate 11 from cracking due to the pins P being pushed up. Therefore, while preventing the semiconductor substrate 11 from cracking, it is possible to thin the semiconductor chip 10 by thinning the first portion 13, that is, a portion of the semiconductor substrate 11 other than the second portions 14 pushed up by the pins P. Therefore, the on-resistance of the semiconductor chip 10, which is a transistor, can be reduced. In the first embodiment, the second portions 14 are disposed at positions away from the outer peripheral edge of the semiconductor substrate 11. Therefore, compared to the case where the pins P are used to push up the outer peripheral edge of the semiconductor substrate 11, by using the pins P to push up the second portions 14, it is easier to stably transmit a pushing-up force to the semiconductor substrate 11.

According to the first embodiment, the semiconductor device 100 includes the first conductive member 20 to which the semiconductor chip 10 is fixed. The hole portions 24 are formed on the surface on a side of the first conductive member 20 on which the second electrode 12b is joined, that is, on the surface on an upper side. A part of each of the second portions 14 is located inside each hole portion 24. Therefore, the protrusion 14e of each second portion 14 that protrudes further toward the lower side than the first portion 13 is caught by the inner surface of each hole portion 24, thereby suppressing movement of the semiconductor chip 10 in a direction orthogonal to the thickness direction Z with respect to the first conductive member 20. Accordingly, for example, when the bonding material 50 is melted to join the semiconductor chip 10 to the first conductive member 20, it is possible to suppress displacement of the semiconductor chip 10 in a direction orthogonal to the thickness direction Z with respect to the first conductive member 20.

Also, for example, if the hole portions 24 are not formed, a dimension of the bonding material 50 in the thickness direction Z needs to be set to a size that allows the protrusions 14e to be embedded in the bonding material 50. Therefore, in this case, the dimension of the bonding material 50 in the thickness direction Z becomes large, and electrical resistance between the first conductive member 20 and the second electrode 12b becomes large. In contrast, by allowing the protrusions 14e to be inserted into the hole portions 24, the dimension of the bonding material 50 in the thickness direction Z can be made smaller than the dimension T3 of each protrusion 14e in the thickness direction Z. Therefore, the dimension of the bonding material 50 in the thickness direction Z can be reduced, and the electrical resistance between the first conductive member 20 and the second electrode 12b can be prevented from increasing.

In addition, in the first embodiment, the portion of the second electrode 12b which is formed on the surface on the lower side of the first portion 13 is electrically joined to the surface on the upper side of the first conductive member 20 via the bonding material 50. On the other hand, due to the formation of the hole portions 24, the second electrode 12b formed on each protrusion 14e of each second portion 14 is less likely to be electrically joined to the first conductive member 20. Therefore, the current flowing through the semiconductor chip 10 flows through the first portion 13 which is thinner than the second portions 14, and is likely to flow from one of the first electrode 12a and the second electrode 12b to the other. Therefore, even if the second portions 14 thicker than the first portion 13 are provided, the on-resistance of the semiconductor chip 10 can be reduced by making the first portion 13 thin.

According to the first embodiment, each hole portion 24 is a through-hole penetrating the first conductive member 20 in the thickness direction Z. Therefore, the holes 24 can be easily formed by press working to punch out a part of the first conductive member 20. When the outer shape of first conductive member 20 is formed by punching out a part of a plate-like member by press working, the holes 24 can be formed at the same time as the press working that forms the outer shape of first conductive member 20. In addition, even if the paste material 50p gets into the holes 24 when the paste material 50p is applied to the upper surface of the first conductive member 20, the paste material 50p can easily escape downward within the holes 24. This makes it easier to prevent the second electrode 12b formed on the protrusion 14e of each second portion 14, which is inserted into each hole 24 from above, from being joined to the first conductive member 20 by the bonding material 50. In addition, since the second electrode 12b formed on the surface on the lower side of each of the second portions 14 does not face a part of the first conductive member 20 in the thickness direction Z, the current is unlikely to flow between the first electrode 12a and the second electrode 12b formed on the surface on the lower side of each of the second portions 14. Therefore, even if the second portions 14 are provided, the on-resistance of the semiconductor chip 10 can be reduced by making the first portion 13 thin.

According to the first embodiment, the dimension T2 of each second portion 14 in the thickness direction Z is equal to or greater than twice the dimension T1 of the first portion 13 in the thickness direction Z. Therefore, the strength of the semiconductor substrate 11 in the second portions 14 can be further improved. This makes it possible to further prevent the second portions 14 from cracking when pushed up by the pins P, and therefore makes it possible to further prevent the semiconductor substrate 11 from cracking.

According to the first embodiment, the second portions 14 are located, as viewed in the thickness direction Z, inside the region EA of the semiconductor substrate 11 on which the semiconductor element 11a is formed. Therefore, the semiconductor substrate 11 can be made smaller in the direction orthogonal to the thickness direction Z, compared to when the second portions 14 are disposed outside the region EA as viewed in the thickness direction Z. This makes it possible to prevent the semiconductor chip 10 from becoming large in size in a direction orthogonal to the thickness direction Z.

According to the first embodiment, the dimension W1 of each second portion 14 in the first direction X (one direction) orthogonal to the thickness direction Z is greater than 0.5 times and less than twice the dimension W2 of each second portion 14 in the second direction Y (the other direction) orthogonal to both the thickness direction Z and the first direction X. Here, the second portions 14 may be any size as long as they can be pushed up by the pins P. Therefore, when the second portions 14 have a shape extending in a predetermined direction orthogonal to the thickness direction Z, the second portions 14 become unnecessarily large in the predetermined direction. In contrast to this, by making the dimension W1 larger than 0.5 times the dimension W2 and smaller than twice the dimension W2, the difference between the dimension W1 and the dimension W2 can be reduced. This makes it possible to prevent the second portions 14 from becoming unnecessarily large in the predetermined direction orthogonal to the thickness direction Z. Therefore, it is possible to prevent an increase in the number of portions of the semiconductor substrate 11 having a large dimension in the thickness direction Z, and thereby prevent an increase in the on-resistance of the semiconductor chip 10.

According to the first embodiment, the semiconductor substrate 11 has the plurality of second portions 14 disposed away from each other. Therefore, when the semiconductor chip 10 is separated from the adhesive tape DS, the plurality of second portions 14 can be pushed up by the plurality of pins P, respectively. This allows the pushing-up force applied to the semiconductor substrate 11 from each pin P to be reduced. Therefore, the semiconductor substrate 11 can be further prevented from cracking due to the pins P being pushed up. In addition, since the pushing-up forces applied from the plurality of pins P to the plurality of second portions 14 can be made small, the semiconductor substrate 11 is less likely to crack even if the strength of the second portions 14 is low compared to a case where the semiconductor chip 10 is pushed up by one pin P. Therefore, compared to the case where the semiconductor chip 10 is pushed up by one pin P, the dimension T2 of each second portion 14 in the thickness direction Z can be reduced. Therefore, even in the second portions 14, which have a larger dimension in the thickness direction Z than the first portion 13, it is easy to reduce the dimension in the thickness direction Z. Therefore, even if the current flowing in the semiconductor chip 10 flows through the second portions 14, the on-resistance of the semiconductor chip 10 can be prevented from increasing. In addition, in the first embodiment, the plurality of second portions 14 are disposed at positions away from the outer peripheral edge of the semiconductor substrate 11. Therefore, when the plurality of pins P push up the plurality of second portions 14, the plurality of pins P can be spaced closer to each other than when the plurality of pins P push up the outer peripheral edge of the semiconductor substrate 11. This makes it possible to shorten the distance between the portions of the semiconductor substrate 11 that are pushed up by the plurality of pins P, making these portions less likely to bend. Therefore, the semiconductor substrate 11 can be easily pushed up by the plurality of pins P in a stable manner.

According to the first embodiment, the plurality of second portions 14 include the plurality of pairs 14p of the second portions 14, in which two second portions 14 are arranged side by side with a space therebetween in the first direction X. The plurality of pairs 14p of the second portions 14 are arranged side by side with a space therebetween in the second direction Y. Therefore, as in the above-described second thinning step S3, by moving the dicing blade B in the first direction X and the second direction Y to grind the wafer W, the plurality of second portions 14 can be easily formed.

According to the first embodiment, as viewed in the thickness direction Z, a total value of the areas of the plurality of second portions 14 is smaller than the area of the first portion 13. Therefore, even if the current flows between the first electrode 12a and the second electrode 12b through the second portions 14, which are thicker than the first portion 13, the effect of the electrical resistance of the second portions 14 on the on-resistance of the semiconductor chip 10 can be reduced. Therefore, even if the relatively thick second portions 14 are provided, the on-resistance of the semiconductor chip 10 can be reduced by making the first portion 13 thin. In particular, according to the first embodiment, as viewed in the thickness direction Z, a total value of the areas of the plurality of second portions 14 is less than or equal to one tenth of the area of the first portion 13. Therefore, the effect of the electrical resistance of the second portions 14 on the on-resistance of the semiconductor chip 10 can be more suitably reduced. Therefore, the on-resistance of the semiconductor chip 10 can be more suitably reduced.

According to the first embodiment, the method for manufacturing the semiconductor device 100 includes thinning the wafer W on which the plurality of chip regions Wa are formed, that is, the above-described first thinning step S2 and second thinning step S3. The method for manufacturing the semiconductor device 100 includes cutting between the plurality of chip regions Wa in the wafer W fixed on the adhesive tape DS to divide the wafer W into a plurality of semiconductor chips 10, that is, the above-described singulation step S5. The method for manufacturing the semiconductor device 100 includes separating each of the semiconductor chips 10 from the adhesive tape DS, that is, the above-described pickup step S6. The thinning of the wafer includes forming the first portion 13 and the second portions 14 in each of the chip regions Wa. Separating each semiconductor chip 10 from the adhesive tape DS includes pushing up each semiconductor chip 10 in the thickness direction Z from below by the pins P located at positions overlapping the second portions 14 as viewed in the thickness direction Z. Therefore, the portions of the semiconductor substrate 11 that are pushed up by the pins P in the pickup step S6 can be the second portions 14 that are thicker than the first portion 13. Therefore, in the pickup step S6, the semiconductor substrate 11 can be prevented from cracking.

According to the first embodiment, the first portion 13 and the second portions 14 are formed in each chip region Wa by blade dicing. Therefore, unlike the case where the first portion 13 and the second portions 14 are formed by removing the wafer W by etching, for example, it is unnecessary to partially mask the wafer W. That is, it is unnecessary to perform a photolithography process and an etching process to form the first portion 13 and the second portions 14 in each chip region Wa. Therefore, the number of steps required for the process of forming the first portion 13 and the second portions 14 can be reduced. In other words, by forming the first portion 13 and the second portions 14 by blade dicing, the time required for the process of forming the first portion 13 and the second portions 14 can be shortened compared to the case where the photolithography process and the etching process are performed. In addition, the first portion 13 and the second portions 14 can be formed by using a processing machine for performing blade dicing when cutting the wafer W into a plurality of semiconductor chips 10. Therefore, it is unnecessary to prepare a new processing machine for forming the first portion 13 and the second portions 14.

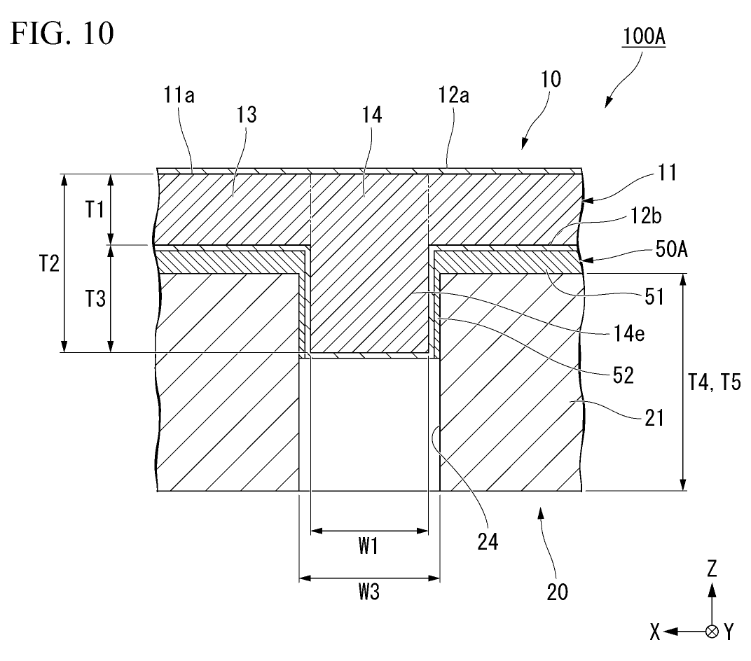

FIG. 10 is a cross-sectional view showing a part of a semiconductor device 100A according to a modification example of the first embodiment. In the semiconductor device 100A shown in FIG. 10, a bonding material 50A has a first bonding portion 51 and a second bonding portion 52. The first bonding portion 51 electrically joins the second electrode 12b formed on the surface on the lower side of the first portion 13 to the surface on the upper side of the first conductive member 20. The second bonding portion 52 electrically joins the second electrode 12b formed on the side surface of the protrusion 14e and the inner surface of the hole portion 24. In other words, in the semiconductor device 100A, a part of the bonding material 50A is embedded between the outer surface of the protrusion 14e and the inner surface of the hole portion 24. By providing the second bonding portion 52, the connection area between the second electrode 12b and the first conductive member 20 connected via the bonding material 50A can be increased. Therefore, the electrical resistance between the second electrode 12b and the first conductive member 20 can be made lower than when the second bonding portion 52 is not provided. Even in such a case, as described above, the current flowing between the first electrode 12a and the second electrode 12b is likely to flow through the first portion 13, which has a lower electrical resistance than the second portion 14. Therefore, by making the first portion 13 thin, the on-resistance of the semiconductor chip 10 is easily reduced. The other configuration of the semiconductor device 100A is the same as the other configuration of the semiconductor device 100.

### Second embodiment

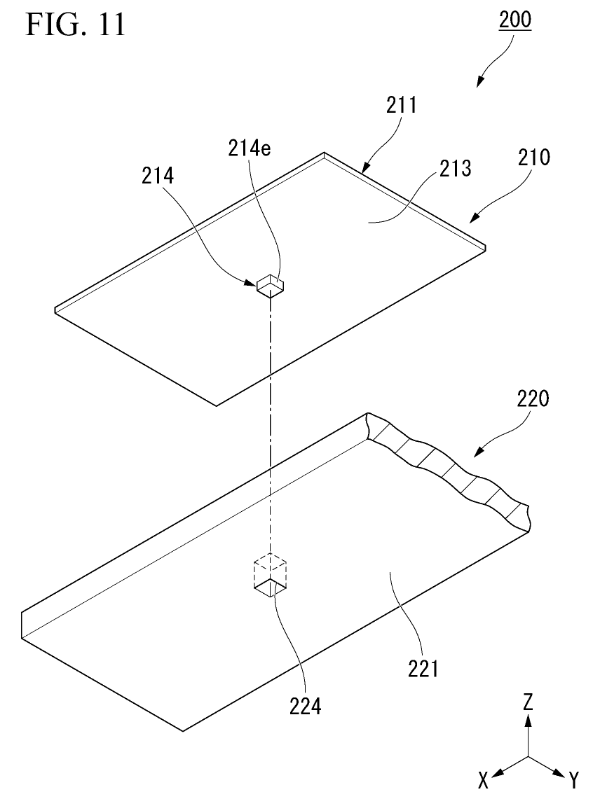

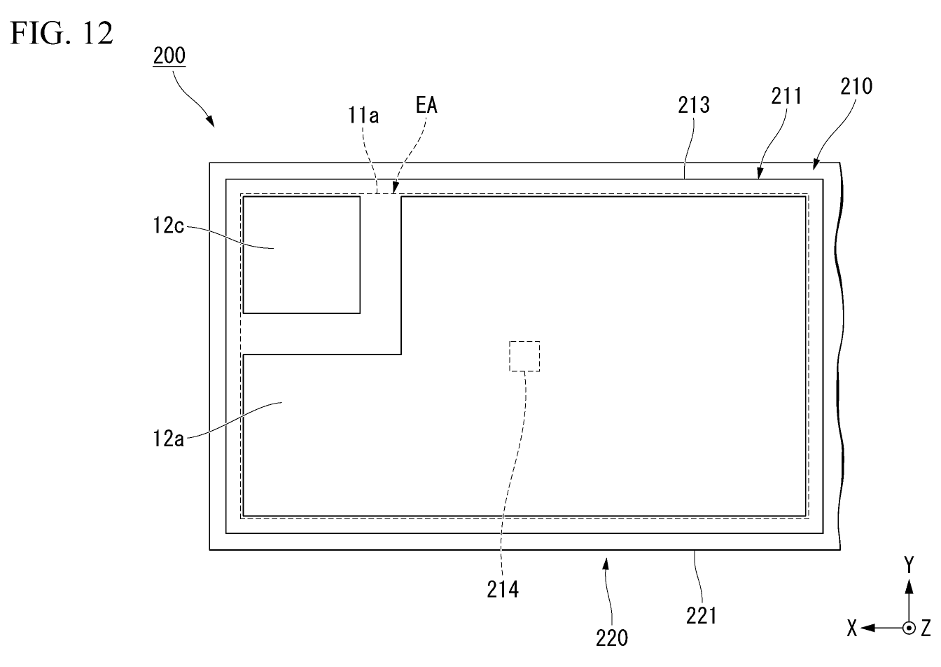

FIG. 11 is an exploded perspective view showing a part of a semiconductor device 200 according to a second embodiment. A second electrode 12b of a semiconductor chip 210 is not shown in FIG. 11. FIG. 12 is a view of a part of the semiconductor device 200 according to the second embodiment as viewed from above (+Z side). A second conductive member 30, a resin portion 40, and a third conductive member are not shown in FIG. 12. In the following description, the same configuration as that in the above-described embodiment may be appropriately denoted by the same reference numerals, and description thereof may not be repeated.

As shown in FIG. 11, the semiconductor device 200 according to the second embodiment has the semiconductor chip 210 and a first conductive member 220. The semiconductor chip 210 has a semiconductor substrate 211. The semiconductor substrate 211 has a first portion 213 and a second portion 214. The semiconductor substrate 211 in the second embodiment has only one second portion 214, unlike the first embodiment. The first portion 213 is the entire portion of the semiconductor substrate 211 except for a single second portion 214. The dimension of the second portion 214 in the thickness direction Z is greater than the dimension of the first portion 213 in the thickness direction Z.

As shown in FIG. 12, the single second portion 214 is the central portion in the second direction Y at the central portion in the first direction X of the semiconductor substrate 211. The single second portion 214 is a portion including the center of the semiconductor substrate 211 in the first direction X and the center of the semiconductor substrate 211 in the second direction Y. The single second portion 214 is disposed away from the outer peripheral edge of the semiconductor substrate 211 as viewed in the thickness direction Z. The single second portion 214 has a protrusion 214e that protrudes further toward the lower side than the surface on the lower side of the first portion 213. The single second portion 214 is located, as viewed in the thickness direction Z, inside the region EA of the semiconductor substrate 211 on which the semiconductor element 11a is formed. The single second portion 214 is disposed at a position overlapping the first electrode 12a as viewed in the thickness direction Z. As viewed in the thickness direction Z, the area of the single second portion 214 is smaller than the area of the first portion 213. As viewed in the thickness direction Z, the area of the single second portion 214 is less than or equal to one fortieth of the area of the first portion 213. The other configuration of the single second portion 214 is the same as the other configuration of the second portions 14 in the first embodiment. The other configuration of the semiconductor chip 210 is the same as the other configuration of the semiconductor chip 10 in the first embodiment.

As shown in FIG. 11, the first conductive member 220 has a first portion to be connected 221 to which the semiconductor chip 210 is fixed. The first portion to be connected 221 has only one hole portion 224 formed therein. The single hole portion 224 is disposed at a position overlapping the single second portion 214 as viewed in the thickness direction Z. Although not shown in the drawing, a part of the protrusion 214e of the single second portion 214 protruding further toward the lower side than the first portion 213 is inserted into the single hole portion 224. The hole portion 224 has the same configuration as each hole portion 24 in the first embodiment, except that it is formed at a different position. The first conductive member 220 has the same configuration as the first conductive member 20 in the first embodiment, except that the number of hole portions 224 formed is one. The other configuration of the semiconductor device 200 is the same as the other configuration of the semiconductor device 100 in the first embodiment.

According to the second embodiment, as in the first embodiment, by pushing up the second portion 214, which is thicker than the first portion 213, with the pin P in the above-described pickup step S6, the semiconductor substrate 211 can be prevented from cracking.

According to the second embodiment, the second portion 214 is a portion including the center of the semiconductor substrate 211 in the first direction X and the center of the semiconductor substrate 211 in the second direction Y. Therefore, when the single second portion 214 is pushed up by the pin P, the pin P can stably push up the semiconductor chip 210. Therefore, in the above-described pickup step S6, the semiconductor chip 210 can be stably separated from the adhesive tape DS while preventing the semiconductor substrate 211 from cracking. In addition, since there is only one second portion 214, the number of portions in the semiconductor substrate 211 that are thicker than the first portion 213 can be reduced. This makes it possible to prevent the on-resistance of the semiconductor chip 210 from increasing.

According to the second embodiment, as viewed in the thickness direction Z, the area of the single second portion 214 is smaller than the area of the first portion 213. Therefore, even if the current flows between the first electrode 12a and the second electrode 12b through the second portion 214, which is thicker than the first portion 213, the effect of the electrical resistance of the second portion 214 on the on-resistance of the semiconductor chip 210 can be reduced. Therefore, even if the relatively thick second portion 214 is provided, the on-resistance of the semiconductor chip 10 can be reduced by making the first portion 213 thin. In particular, according to the second embodiment, as viewed in the thickness direction Z, the area of the single second portion 214 is less than or equal to one fortieth of the area of the first portion 213. Therefore, the effect of the electrical resistance of the second portion 214 on the on-resistance of the semiconductor chip 210 can be more suitably reduced. Therefore, the on-resistance of the semiconductor chip 210 can be more suitably reduced.

According to at least one of the embodiments described above, the semiconductor device has a conductive member and a semiconductor chip fixed to the conductive member. The semiconductor chip has a semiconductor substrate on which a semiconductor element is formed, a first electrode formed on a surface on a first side (upper side) of the semiconductor substrate in the thickness direction Z, and a second electrode formed on a surface on a second side (lower side) opposite to the first side of the semiconductor substrate in the thickness direction Z. The semiconductor substrate has a first portion including an outer peripheral edge of the semiconductor substrate as viewed in the thickness direction Z and a second portion disposed away from the outer peripheral edge as viewed in the thickness direction Z. The second portion is disposed at a position different from the first portion as viewed in the thickness direction Z. A surface on the first side of the first portion is a part of the surface on the first side of the semiconductor substrate. A surface on the first side of the second portion is another part of the surface on the first side of the semiconductor substrate. A surface on the second side of the first portion is a part of the surface on the second side of the semiconductor substrate. A surface on the second side of the second portion is another part of the surface on the second side of the semiconductor substrate. The conductive member is disposed on the second side of the semiconductor chip. The second portion has a protrusion that protrudes further toward the second side than the surface on the second side of the first portion. A portion of the second electrode formed in the first portion is electrically joined to the conductive member via a bonding material. The dimension of the second portion in the thickness direction Z is greater than the dimension of the first portion in the thickness direction Z. Accordingly, even if the first portion is thinned, the semiconductor substrate can be prevented from cracking by pushing up the second portion with a pin P when picking up the semiconductor chip.

The number of the second portions is not particularly limited as long as it is one or more. The entirety of the protrusion of each second portion may be located inside each hole portion formed in the conductive member. The semiconductor substrate may have a third portion having a dimension in the thickness direction that is different from those of both the first portion and the second portion. In this case, the third portion has, for example, a protrusion that protrudes further in the thickness direction than the first portion. In this case, the protruding height of the protrusion of the second portion that protrudes further in the thickness direction than the first portion and the protruding height of the protrusion of the third portion that protrudes further in the thickness direction than the first portion are different from each other. The semiconductor chip of the semiconductor device may be any type of device as long as it has a semiconductor substrate on which a semiconductor element is formed. The semiconductor chip may be a device other than a transistor, such as a diode or a thyristor. The semiconductor device may include a semiconductor chip, and may not include any members other than the semiconductor chip. The first direction may be any direction as long as it is orthogonal to the thickness direction. The first direction may be a direction inclined with respect to a direction in which an edge of the semiconductor substrate extends. The second direction may be a direction inclined with respect to a direction in which an edge of the semiconductor substrate extends.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a conductive member, and
a semiconductor chip fixed to the conductive member,
wherein the semiconductor chip has
a semiconductor substrate on which a semiconductor element is formed,
a first electrode formed on a surface on a first side of the semiconductor substrate in the thickness direction, and
a second electrode formed on a surface on a second side opposite to the first side of the semiconductor substrate in the thickness direction,
the semiconductor substrate has
a first portion including an outer peripheral edge of the semiconductor substrate as viewed in the thickness direction and
a second portion disposed away from the outer peripheral edge as viewed in the thickness direction,
the second portion is disposed at a position different from the first portion as viewed in the thickness direction,
a surface on the first side of the first portion is a part of the surface on the first side of the semiconductor substrate,
a surface on the first side of the second portion is another part of the surface on the first side of the semiconductor substrate,
a surface on the second side of the first portion is a part of the surface on the second side of the semiconductor substrate,
a surface on the second side of the second portion is another part of the surface on the second side of the semiconductor substrate,
the conductive member is disposed on the second side of the semiconductor chip,
a portion of the second electrode formed on the surface on the second side of the first portion is electrically joined to the conductive member via a bonding material,
a dimension of the second portion in the thickness direction is greater than a dimension of the first portion in the thickness direction, and
the second portion protrudes further toward the second side than the first portion.

2. The semiconductor device according to claim 1,
wherein a hole is formed on a surface of the conductive member on a side on which the second electrode is joined, and
a part of the second portion is located inside the hole.

3. The semiconductor device according to claim 2,
wherein the hole is a through-hole penetrating the conductive member in the thickness direction.

4. The semiconductor device according to claim 1,
wherein the dimension of the second portion in the thickness direction is equal to or greater than twice the dimension of the first portion in the thickness direction.

5. The semiconductor device according to claim 1,
wherein the second portion is located inside a region of the semiconductor substrate on which the semiconductor element is formed, as viewed in the thickness direction.

6. The semiconductor device according to claim 1,
wherein a dimension of the second portion in a first direction orthogonal to the thickness direction is greater than 0.5 times and less than twice a dimension of the second portion in a second direction orthogonal to both the thickness direction and the first direction.

7. The semiconductor device according to claim 1,
wherein the semiconductor substrate has a plurality of the second portions including the second portion, and
wherein the plurality of the second portions are arranged apart from each other.

8. The semiconductor device according to claim 7,
wherein the plurality of the second portions include a plurality of pairs of the second portions in which the two second portions are arranged side by side with a space therebetween in a first direction orthogonal to the thickness direction, and
the plurality of the pairs of the second portions are arranged side by side with a space therebetween in a second direction orthogonal to both the thickness direction and the first direction.

9. The semiconductor device according to claim 7,
wherein, as viewed in the thickness direction, a total value of areas of the plurality of the second portions is smaller than an area of the first portion.

10. The semiconductor device according to claim 9,
wherein, as viewed in the thickness direction, the total value of areas of the plurality of the second portions is less than or equal to one tenth of the area of the first portion.

11. The semiconductor device according to claim 1,
wherein the second portion is a portion including
a center of the semiconductor substrate in a first direction orthogonal to the thickness direction and
a center of the semiconductor substrate in a second direction orthogonal to both the thickness direction and the first direction.

12. The semiconductor device according to claim 11,
wherein, as viewed in the thickness direction, an area of the second portion is smaller than an area of the first portion.

13. The semiconductor device according to claim 12,
wherein, as viewed in the thickness direction, the area of the second portion is less than or equal to one fortieth of the area of the first portion.

14. A method for manufacturing a semiconductor device including a semiconductor chip fixed to a conductive member, the method comprising:
thinning a wafer on which a plurality of chip regions to be processed into each of the semiconductor chip are formed;
cutting the wafer between the plurality of chip regions in the wafer fixed on an adhesive tape to divide the wafer into a plurality of the semiconductor chips; and
separating each of the semiconductor chips from the adhesive tape,
wherein the semiconductor chip has
a semiconductor substrate on which a semiconductor element is formed,
a first electrode formed on a surface on a first side of the semiconductor substrate in the thickness direction, and
a second electrode formed on a surface on a second side opposite to the first side of the semiconductor substrate in the thickness direction,
the semiconductor substrate has
a first portion including an outer peripheral edge of the semiconductor substrate as viewed in the thickness direction and
a second portion disposed away from the outer peripheral edge as viewed in the thickness direction,
the second portion is disposed at a position different from the first portion as viewed in the thickness direction,
a surface on the first side of the first portion is a part of the surface on the first aide of the semiconductor substrate,
a surface on the first side of the second portion is another part of the surface on the first side of the semiconductor substrate,
a surface on the second side of the first portion is a part of the surface on the second side of the semiconductor substrate,
a surface on the second side of the second portion is another part of the surface on the second side of the semiconductor substrate,
the conductive member is disposed on the second side of the semiconductor chip,
a portion of the second electrode formed on the surface on the second side of the first portion is electrically joined to the conductive member via a bonding material,
a dimension of the second portion in the thickness direction is greater than a dimension of the first portion in the thickness direction,
the second portion protrudes further toward the second side than the first portion,
the thinning of the wafer includes forming the first portion and the second portion in each of the chip regions, and
the separating of each of the semiconductor chips from the adhesive tape includes pushing up each of the semiconductor chips in the thickness direction from the second side by a pin disposed at a position overlapping the second portion as viewed in the thickness direction.

15. The method for manufacturing a semiconductor device according to claim 14,
wherein the forming of the first portion and the second portion in each of the chip regions is performed by blade dicing.
